(19) United States
(12) Patent Application Publication
(10) Pub. No.: US 2012/0034782 A1
(43) Pub. Date: Feb. 9, 2012

(54) Method of Forming Fine Patterns

(75) Inventor: Choong Bae Kim, Yongin-si (KR)

(73) Assignee: HYNIX SEMICONDUCTOR INC., Icheon-si (KR)

(21) Appl. No.: 12/958,213

(22) Filed: Dec. 1, 2010

(30) Foreign Application Priority Data
Aug. 4, 2010 (KR) 10-2010-0075254
Aug. 4, 2010 (KR) 10-2010-00752543

(51) Int. Cl. H01L 21/311

(52) U.S. Cl. 438/694; 257/E21.257

(57) ABSTRACT

A method of forming fine patterns according to an aspect of the present disclosure comprises stacking a hard mask layer and a first auxiliary layer over an underlying layer, removing regions of the first auxiliary layer, thereby forming first auxiliary patterns to expose regions of the hard mask layer, filling between the first auxiliary patterns with a second auxiliary layer, wherein a material of the second auxiliary layer is different from that of the first auxiliary layer, lowering a height of the second auxiliary layer by removing the second auxiliary layer to expose sidewalls of the first auxiliary patterns, forming spacers on the exposed sidewalls of the first auxiliary patterns to expose regions of the second auxiliary layer, wherein a material of the spacers is different from that of the second auxiliary layer, removing the exposed regions of the second auxiliary layer, removing the spacers and the first auxiliary patterns to expose regions of the hard mask layer and removing the exposed regions of the hard mask layer, thereby forming hard mask patterns.

### CROSS-REFERENCE TO RELATED APPLICATION

Priority to Korean patent application number 10-2010-0075254 filed on Aug. 4, 2010, the entire disclosure of which is incorporated by reference herein, is claimed.

### BACKGROUND

An exemplary embodiment relates generally to a method of forming the patterns of a semiconductor device and, more particularly, to a method of uniformly forming fine patterns each being narrower than an exposure resolution limit.

The patterns of a semiconductor device are typically formed by using a photolithography process. The photolithography process generally includes a process of depositing a photoresist layer on an underlying layer for target patterns, a process of exposing the photoresist layer, and a process of developing the exposed photoresist layer. Photoresist patterns are formed on the underlying layer by the photolithography process.

The photoresist patterns are used as an etch mask when patterning the patterns of the semiconductor device. Accordingly, the size of each of the photoresist patterns serves as a factor in determining the size of each of the patterns of the semiconductor device.

The size of the photoresist pattern is determined by the exposure resolution limit, and therefore there is a limit to the fineness of the photoresist pattern due to the exposure resolution limit. Accordingly, there is a disadvantage in that fine patterns of 40 nm or less are difficult to form by the known photolithography process. A variety of methods for overcoming the exposure resolution limit have been proposed. However, various known methods are disadvantageous in that it is difficult to secure the uniformity of the patterns, each having a narrower width than the exposure resolution limit. In the case of a NAND flash memory device, if gate patterns or isolation trenches are irregularly formed, the threshold voltage distribution characteristics, etc. of a semiconductor device may be adversely affected.

### BRIEF SUMMARY

An exemplary embodiment relates to a method of forming fine patterns which is capable of improving the uniformity of patterns each having a narrower width than the exposure resolution limit.

A method of forming fine patterns according to an aspect of the present disclosure comprises stacking a hard mask layer and a first auxiliary layer over an underlying layer, removing regions of the first auxiliary layer, thereby forming first auxiliary patterns to expose regions of the hard mask layer, filling between the first auxiliary patterns with a second auxiliary layer, wherein a material of the second auxiliary layer is different from that of the first auxiliary layer, lowering a height of the second auxiliary layer by removing the second auxiliary layer to expose sidewalls of the first auxiliary patterns, forming spacers on the exposed sidewalls of the first auxiliary patterns to expose regions of the second auxiliary layer, wherein a material of the spacers is different from that of the second auxiliary layer, removing the exposed regions of the second auxiliary layer, removing the spacers and the first auxiliary patterns to expose regions of the hard mask layer and removing the exposed regions of the hard mask layer, thereby forming hard mask patterns.

The first auxiliary layer preferably comprises polysilicon or a nitride layer having a higher hardness than a spin-on carbon (SOC) layer or an amorphous carbon layer. The second auxiliary layer preferably comprises an oxide layer or a spin-on carbon (SOC) layer. The spacers preferably comprise polysilicon or a spin-on carbon (SOC) layer other than an oxide layer. The first auxiliary layer and the spacers may be made of the same material or of different materials.

The height of the second auxiliary layer preferably is lowered by using a chemical mechanical polishing (CMP) method, a dry etch method, or a wet etch method either alone or in combinations of two or more of the CMP method, the dry etch method, and the wet etch method.

### BRIEF DESCRIPTION OF THE DRAWINGS

FIGS. 1A to 1G are diagrams illustrating a method of forming fine patterns according to an embodiment of this disclosure.

### DESCRIPTION OF EMBODIMENT

Hereinafter, an exemplary embodiment of the present disclosure is described in detail with reference to the accompanying drawings. The drawing figures are provided to allow those having ordinary skill in the art to understand the scope of the embodiment of the disclosure.

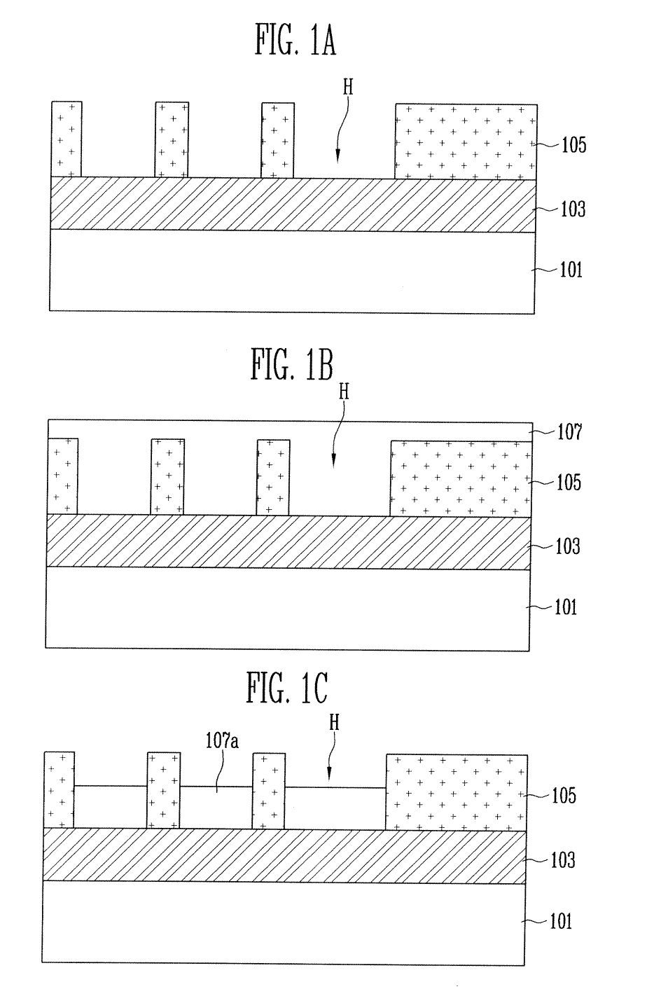

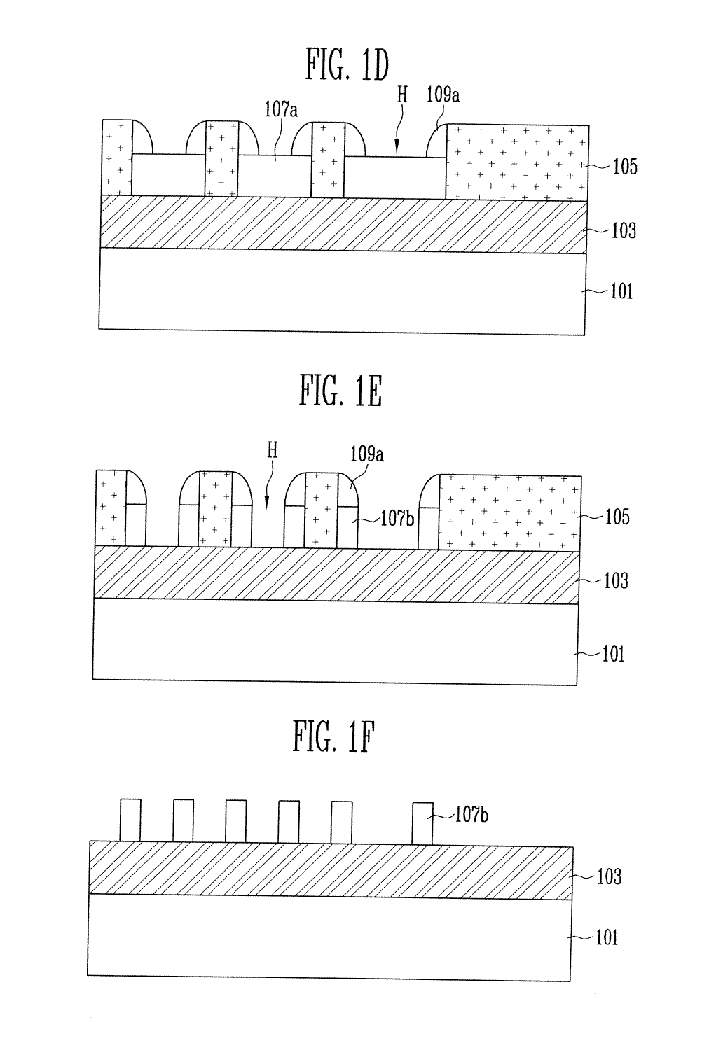

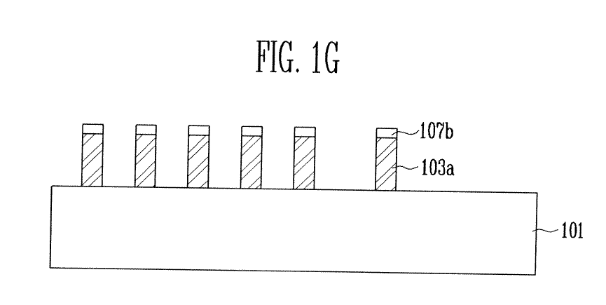

FIGS. 1A to 1G are diagrams illustrating a method of forming fine patterns according to an embodiment of this disclosure.

Referring to FIG. 1A, a hard mask layer 103 and a first auxiliary layer 105 are stacked over an underlying layer 101 for target patterns.

The underlying layer 101 may be a semiconductor substrate, an insulating layer formed on a semiconductor substrate, a conductive layer formed on a semiconductor substrate, or an auxiliary hard mask layer formed on an insulating layer or a conductive layer, for example.

The hard mask layer 103 is made of a material selected depending on the type of the underlying layer 101. Thus, it is preferred that the hard mask layer 103 be made of a material that is different from the underlying layer 101 by taking the respective etch selectivities of the underlying layer 101 and the hard mask layer 103 into consideration.

It is preferred that the first auxiliary layer 105 be made of a material that is different from the material of the hard mask layer 103 by taking the respective etch selectivities of the first auxiliary layer and the hard mask layer 103 into consideration.

Furthermore, the first auxiliary layer 105 should be sufficiently thick to allow the sidewalls of the first auxiliary layer 105 to be subsequently exposed to form the spacers. For example, the first auxiliary layer 105 preferably is formed in a thickness of 300 Å to 2000 Å. It is also preferred that the first auxiliary layer 105 comprise polysilicon or a nitride layer, having a higher hardness than a spin-on carbon (SOC) layer and an amorphous carbon layer, so that the first auxiliary layer 105 maintains its form without collapse even though it is relatively thick.

Next, regions of the first auxiliary layer 105 are removed by an etch process so that a plurality of holes H through which the hard mask layer 103 is exposed are formed in the first auxiliary layer 105. The holes H preferably are formed by patterning the first auxiliary layer 105 using a photolithography process. Accordingly, the first auxiliary patterns, which are isolated by the holes H, are formed.

Referring to FIG. 1B, the holes H (i.e., between the first auxiliary patterns) are filled with a second auxiliary layer 107. It is preferred that the second auxiliary layer 107 be made of a material that is different from the material of the first auxiliary layer 105 and the spacers to be subsequently formed by taking into account the respective etch selectivities of the first auxiliary layer 105 and the spacers. For example, the second auxiliary layer 107 preferably comprises an oxide layer or a spin-on carbon (SOC) layer.

Referring to FIG. 1C, the height of the second auxiliary layer is lowered to expose a portion of the sidewalls of the first auxiliary layer 105 through the holes H. To lower the height of the second auxiliary layer, an etch process, such as etch-back process, preferably is performed. Furthermore, to lower the height of the second auxiliary layer, at least one of a chemical mechanical polishing (CMP) method, a dry etch method, and a wet etch method preferably is used.

The sidewalls of the first auxiliary layer 105 preferably are exposed to a depth of 30% to 70% of the thickness of the first auxiliary layer 105, thereby forming a second auxiliary layer 107a.

Referring to FIG. 1D, spacers 109a are formed on the exposed sidewalls of the first auxiliary layer 105. The spacers 109a preferably comprise a material that is different from, or the same material as, the material of the first auxiliary layer 105. Furthermore, the spacers 109a preferably are made of a material that is different from the material of the second auxiliary layer.

The spacers preferably are formed by depositing a third auxiliary layer, having a thickness controlled not to fill the holes H, on a surface of the first auxiliary layer 105 and a surface of the second auxiliary layer 107a lower than the first auxiliary layer 105 and then etching the third auxiliary layer using an etch process, such as etch-back process, for example, to expose the second auxiliary layer 107a. The deposition thickness of the third auxiliary layer formed on the sidewalls of the first auxiliary layer 105 (i.e., the upper sidewalls of the hole patterns H) determines the width of a hard mask pattern to be formed in a subsequent process. If the third auxiliary layer is formed of an oxide layer, the spacers 109a are asymmetrically formed. Thus, to improve the asymmetry of the spacers 109a, the third auxiliary layer preferably is formed of polysilicon or a spin-on carbon layer other than an oxide layer.

Referring to FIG. 1E, the exposed regions of the second auxiliary layer are removed using the spacers 109a as an etch mask, thereby forming auxiliary patterns 107b. The width of each of the auxiliary patterns 107b is defined by the width of each of the spacers 109a, and the width of the spacer 109a is defined by the deposition thickness of the third auxiliary layer. Accordingly, the width of the auxiliary pattern 107b can be narrower than the exposure resolution limit because it is defined by the deposition thickness of the third auxiliary layer.

Furthermore, since the spacers 109a and the second auxiliary layer are preferably made from different materials, the spacers 109a can be prevented from being removed when etching the second auxiliary layer using the etch selectivity of the second auxiliary layer to the spacers 109a, when etching the second auxiliary layer. Accordingly, although the spacers 109a may have an asymmetrical form, the asymmetrical form of the spacers 109a does not have an effect on the shape of the auxiliary patterns 107b in a process of forming the auxiliary patterns 107b by etching the second auxiliary layer. Accordingly, the auxiliary patterns 107b may have a symmetrical form.

Referring to FIG. 1F, the hard mask layer 103 between the auxiliary patterns 107b is exposed by removing the first auxiliary layer and the spacers. The first auxiliary layer and the spacers may be removed by using an etch-back or strip process, for example. Furthermore, in a case where the first auxiliary layer and the spacers are made of the same material, they can be removed at the same time, thereby simplifying the process.

Referring to FIG. 1G, the exposed regions of the hard mask layer are removed using the auxiliary patterns 107b as an etch mask, thereby forming hard mask patterns 103a. The width of each of the hard mask patterns 103a is defined by the width of each of the auxiliary patterns 107b, and the width of each of the auxiliary patterns 107b is defined by the deposition thickness of the third auxiliary layer which determines the width of the spacers. Accordingly, the width of the hard mask pattern 109a may be narrower than the exposure resolution limit because it is defined by the deposition thickness of the third auxiliary layer.

In the exemplary embodiment of this disclosure, the hard mask layer is etched by using the auxiliary patterns 107b, having a symmetrical form, as an etch mask. Accordingly, the hard mask patterns 103a can be uniformly formed. Furthermore, the patterns of the semiconductor device can be uniformly formed by using the hard mask patterns 103a, having a symmetrical form, as an etch mask.

For example, in a case where the gate patterns or the isolation trenches of a semiconductor device are formed using the hard mask patterns 103a as an etch mask according to an embodiment of this disclosure, the gate patterns or the isolation trenches can be uniformly formed and have a symmetrical form. Accordingly, this disclosure can improve a phenomenon in which the threshold voltage distribution characteristic of the semiconductor device is adversely affected because the gate patterns or the isolation trenches are formed to have an irregular width.

In accordance with this disclosure, the width of the hard mask pattern can be defined by controlling the width of the spacer formed on the sidewalls of the first auxiliary layer. Accordingly, hard mask patterns being narrower than the exposure resolution limit can be formed. Furthermore, a semiconductor device having patterns each narrower than the exposure resolution limit can be manufactured by patterning the patterns using the hard mask pattern narrower than the exposure resolution limit as an etch mask.

Furthermore, in accordance with this disclosure, the second auxiliary layer formed on the lower side of the spacers preferably comprises a different material from the material of the spacers. Although the spacers are asymmetrically formed, when the auxiliary patterns are formed by etching the second auxiliary layer using the spacers as an etch mask, the auxiliary patterns can be prevented from being formed in an asymmetrical form like the spacers by selection of the etch selectivity of the second auxiliary layer for the spacers and can be symmetrically formed. Moreover, if the hard mask patterns are etched using the auxiliary patterns as an etch mask, the hard mask patterns can also be symmetrically formed. If the patterns of a semiconductor device are patterned by using the hard mask patterns of a symmetrical form as an etch mask, the patterns of the semiconductor device can be uniformly formed.

What is claimed is:

1. A method of forming fine patterns, comprising:
stacking a hard mask layer and a first auxiliary layer over an underlying layer;
removing regions of the first auxiliary layer, thereby forming first auxiliary patterns to expose regions of the hard mask layer;
filling between the first auxiliary patterns with a second auxiliary layer, wherein a material of the second auxiliary layer is different from that of the first auxiliary layer;
lowering a height of the second auxiliary layer by removing the second auxiliary layer to expose sidewalls of the first auxiliary patterns;
forming spacers on the exposed sidewalls of the first auxiliary patterns to expose regions of the second auxiliary layer, wherein a material of the spacers is different from that of the second auxiliary layer;
removing the exposed regions of the second auxiliary layer;
removing the spacers and the first auxiliary patterns to expose regions of the hard mask layer; and
removing the exposed regions of the hard mask layer, thereby forming hard mask patterns.

2. The method of claim 1, wherein the first auxiliary layer comprises polysilicon or a nitride layer.

3. The method of claim 1, wherein the second auxiliary layer comprises an oxide layer or a spin-on carbon (SOC) layer.

4. The method of claim 1, wherein the spacers comprise polysilicon or a spin-on carbon (SOC) layer.

5. The method of claim 1, wherein the first auxiliary layer and the spacers comprise an identical material.

6. The method of claim 1, wherein the first auxiliary layer and the spacers comprise different materials.

7. The method of claim 1, comprising lowering the height of the second auxiliary layer using at least one of a chemical mechanical polishing (CMP) method, a dry etch method, and a wet etch method.
